(19) United States
(12) Patent Application Publication
(10) Pub. No.: US 2005/0275431 A1
(43) Pub. Date: Dec. 15, 2005

(54) High-speed low-voltage differential signaling buffer using a level shifter

(75) Inventor: Young-Kyun Cho, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/149,308

(22) Filed: Jun. 9, 2005

(30) Foreign Application Priority Data
Jun. 15, 2004 (KR) 10-2004-0043845

(51) Int. Cl. H03K 19/0175

(52) U.S. Cl. 326/83

(57) ABSTRACT

A low voltage differential signaling (LVDS) input buffer includes an NMOS differential amplifying circuit, a PMOS differential amplifying circuit, a first level-shift circuit for the NMOS differential amplifying circuit, a second level-shift circuit for the PMOS differential amplifying circuit and an output coupling circuit. The first level-shift circuit level-shifts a differential input signal to a first input voltage range permitted by the NMOS differential amplifying circuit and the second level-shift circuit level-shifts the differential input signal to a second input voltage range permitted by the PMOS differential amplifying circuit. The output coupling circuit couples a first differential output signal of the NMOS differential amplifying circuit to a second differential output signal of the PMOS differential amplifying circuit to generate a third differential output signal.

### RELATED APPLICATIONS

This application claims priority under 35 USC § 119 to Korean Patent Application No. 2004-43845, filed on Jun. 15, 2004, the contents of which are herein incorporated by reference in their entirety for all purposes.

### BACKGROUND OF THE INVENTION

1. Field of the Invention

The present invention relates to a low voltage differential signaling (LVDS) input buffer, and more particularly to the low voltage differential signaling input buffer especially suited for use in high speed operation in which an output signal maintains a constant voltage level using a level shifter.

2. Description of the Related Art

A low voltage differential signaling (LVDS) protocol, which conforms to ANSI/TIA/EIA-644 standards, is used to transmit data at a high rate of transmission with reduced power consumption and higher noise immunity.

The LVDS receiver (or LVDS buffer) allows for high speed data transmission based on a differential input signal having an extremely small voltage swing, for example, a voltage swing of around 350 mV. Particularly, the LVDS receiver offers advantages such as high immunity to noise since the LVDS receiver operates with high common mode rejection (CMR).

A variety of electronic devices, such as flat panel displays, utilize the LVDS receiver to transmit differential data at high speed. The LVDS receiver is commonly employed for data transfer between, for example, laptop notebook hosts and LCD panel displays since the LVDS approach requires a relatively small number of wires.

The LVDS receiver can support a wide common mode input voltage range, for example, a voltage range of about 2.4 volts, according to the LVDS standard, to allow for a certain amount of common mode noise and a ground potential difference between a driver and the receiver. To guarantee the wide common input voltage range, the LVDS receiver specifies a rail-to-rail common mode range, which can be implemented in an NMOS amplifying circuit and a PMOS amplifying circuit coupled to the NMOS amplifying circuit in parallel.

Additionally, to increase the noise immunity, hysteresis can be provided to the LVDS receiver so that an output signal is not caused to shift in response to the presence of noise on the LVDS input signals. Generally, about 50 mV of hysteresis is required in the LVDS receiver.

In addition, the output signal of the LVDS receiver needs to have a constant voltage level to perform the high speed data transmission since a variation in the output signal voltage level may give rise to a problem such that a DC bias level applied to a comparison circuit receiving output signals from the PMOS and NMOS differential amplifying circuits may be varied. When the DC bias level applied to the comparison circuit is varied, the LVDS receiver may not exhibit an optimal duty cycle and the output signals required for the high speed data transmission.

Moreover, as an operation frequency increases, parasitic capacitance also increases to generate difficulties in high speed data transmission.

FIGS. 1 through 2B are circuit diagrams illustrating a conventional LVDS input buffer, for example of the type disclosed in U.S. Pat. No. 6,535,031, incorporated herein by reference. The conventional LVDS input buffer includes a rail-to-rail gain stage and provides about 50 mV of hysterisis.

FIG. 1 is a circuit diagram illustrating a conventional LVDS input buffer. The LVDS in FIG. 1 includes an NMOS differential amplifying circuit 100a, a PMOS differential amplifying circuit 100b and a comparison circuit 100c. The differential amplifying circuits 100a and 100b may be enabled or disabled depending on whether a first current source 106 and a second current source 107 are turned on or off based on a control register 105 that determines the activation of the LVDS input buffer, wherein the first and second current sources 106 and 107 supply the NMOS and PMOS differential amplifying circuits 100a and 100b with currents I1 and I2, respectively.

Input signals 101, 102 (INA and INB) of a differential input signal are applied to the NMOS differential amplifying circuit 100a through input NMOS transistors 110, 112, respectively, and applied to the PMOS differential amplifying circuit 100b through input PMOS transistors 152, 150, respectively.

Thus, the LVDS buffer includes two differential amplifying circuits 100a and 100b so as to operate normally over a wide range of a common mode voltage of the LVDS input signals INA and INB. For example, the LVDS input signals INA and INB may have the common mode input voltage ranging from about 0 volt to about 2.4 volts when a power supply voltage Vcc is about 2.5 volts.

When the differential input signals INA and INB have a common mode input voltage that is close to ground potential, the PMOS differential amplifying circuit 100b is operative and when the common mode input voltage is close to about 2.4 volts, the NMOS differential amplifying circuit 100a is operative. Thus, based on whether the voltage level of the common mode voltage is closer to 0 volt or 2.4 volts, the NMOS differential amplifying circuit 100a and the PMOS differential amplifying circuit 100b operate complementarily to each other such that one is turned on while the other is turned off. Or, the driving strength of one may be increased while the driving strength of the other is decreased.

In regard of the operation of the NMOS differential amplifying circuit 100a, the LVDS input signal 101 (INA) is applied to a gate of the input NMOS transistor 110, and the LVDS input signal 102 (INB) is applied to a gate of the input PMOS transistor 112. The first current source 106 draws current from sources of the input transistors 110 and 112. A PMOS transistor 120 and a PMOS transistor 122 supply the input transistors 110 and 112 with current from the power supply voltage Vcc, respectively.

PMOS transistors 130 and 132 are current mirrors for the PMOS transistors 120 and 122, respectively, to combine with outputs of the PMOS differential amplifying circuit 100b. The combined outputs of NMOS differential amplifying circuit 100a and the PMOS differential amplifying circuit 100b are provided to the comparison circuit 100c.

Each of the PMOS transistors 140 and 142 has a relatively small transistor size such that the PMOS transistors 140 and 142 have high resistance to any noise that may be present in the LVDS input signals INA and INB of the NMOS differential amplifying circuit 100a. Namely, the NMOS differential amplifying circuit 100a may have hysteresis responsive to the LVDS differential input signals.

The PMOS differential amplifying circuit 100b has a configuration functionally analogous to the configuration described above for the NMOS differential amplifying circuit 100a. PMOS transistors 150 and 152 receive the LVDS input signals INA and INB, respectively, and NMOS transistors 160 and 162 provide current to the PMOS transistors 150 and 152, respectively. Similarly, the second current source 107 supplies the PMOS transistors 150 and 152 with current from the power supply voltage Vcc. NMOS transistors 180 and 182 of the PMOS differential amplifying circuit 100b correspond to the PMOS transistors 140 and 142 of the NMOS differential amplifying circuit 100a, respectively.

The outputs of the NMOS differential amplifying circuit 100a and PMOS differential amplifying circuit 100b are combined and applied to control electrodes of NMOS transistors 192 and 193 in the comparison circuit 100c. The comparison circuit 100c provides a final output signal (logic signal) 194 to logic of a device using the received combined outputs of the NMOS and PMOS differential amplifying circuits 100a and 100b.

As described above, to obtain high transmission speed, the final output signal 194 must maintain a constant voltage level regardless of the common mode voltage level of the differential input signals INA and INB. To maintain the final output signal 194 at the constant voltage level, in the conventional art, the strengths of the first current source for the NMOS differential amplifying circuit and the second current source for the PMOS differential amplifying circuit are adjusted.

FIGS. 2A and 2B are exemplary circuit diagrams illustrating the first and second current sources 106 and 107 of the LVDS input buffer of FIG. 1, respectively.

The first current source 106 of the NMOS differential amplifying circuit 100a raises the level of the current provided to the NMOS differential amplifying circuit 100a when the common mode voltages of the LVDS input signals 101 and 102 are close to the power supply voltage Vcc so that the PMOS differential amplifying circuit 100b stops operating or partially turned off. Thus, the strength of the output signal of the NMOS differential amplifying circuit 100a is increased to complement the decrease in the strength of the output signal of the PMOS differential amplifying circuit 100b when the differential input signals have higher common mode voltages.

The second current source 107 of the PMOS differential amplifying circuit 100b raises the level of the current provided to the PMOS differential amplifying circuit 100b when the common mode voltages of the LVDS input signals 101 and 102 are close to ground (i.e., Vss) so that the NMOS differential amplifying circuit 100a stops operating or partially turned off. Thus, when the differential input signals have lower common mode voltages, the output signal of the PMOS differential amplifying circuit 100b has a complementarily increased strength while the strength of the output signal of the NMOS differential amplifying circuit 100a decreases.

Referring to FIG. 2A, the first and second current sources 106 and 107 are activated depending on the control register 105 that determines the activation of the LVDS input buffer. When NMOS transistors 202 and 204 are turned on by the control register 105, the voltage Vss is applied to respective gates of NMOS transistors 230, 232, 240 and 242 to inactivate the first current source 106. Conversely, when the NMOS transistors 202 and 204 are turned off by the control register 105, the NMOS transistors 230, 232, 240 are activated.

A reference voltage Vref 205 is applied to respective gates of PMOS transistors 210, 212 connected to Vcc. The reference voltage Vref 205 may be designated to have a voltage level corresponding to one-half of the Vcc so that the PMOS transistors 210, 212 are constantly turned on and pulls a constant amount of current from the Vcc source.

The differential input signals 101, 102 (INA and INB) are applied to respective gates of the PMOS transistors 222 and 220. Since the PMOS transistors 220 and 222 have the same threshold voltages Vtp as the input PMOS transistors 150 and 152 of the PMOS differential amplifying circuit 100b, the PMOS transistors 220 and 222 are turned off when the common mode voltages of the differential input signals INA and INB are higher than a voltage level corresponding to Vcc−|Vtp|. In contrast, when the common mode voltages of the differential input signals INA and INB are lower than a voltage level corresponding to Vcc−|Vtp|, the PMOS transistors 220 and 222 are turned on.

Depending on the strength of the PMOS transistors 220 and 222, the current flowing through the NMOS transistor 232 is varied and accordingly, the current flowing through the NMOS transistor 230, which is a current mirror for the NMOS transistor 232, is also varied. The current drawn from the PMOS transistor 210 controls the amount of current provided to the NMOS transistor 240. Therefore, the amount of the current I1 flowing through the NMOS transistor 242 is controlled in response to the common mode voltages of the differential input signals 101 and 102.

To summarize, the higher the common mode voltage of the differential input signals 101 and 102 is than a voltage level corresponding to Vcc−|Vtp|, the greater amount of the current I1 flows. Additionally, the lower the common mode voltage of the differential input signals 101 and 102 is than the voltage level corresponding to Vcc−|Vtp|, the smaller amount of the current I1 flows. Namely, when the common mode voltage of the differential input signals 101 and 102 is higher than the voltage level corresponding to Vcc−|Vtp|, the PMOS differential amplifying circuit 100b stops operating so that the amount of the current I1 flowing through the NMOS differential amplifying circuit 100a is increased to compensate for a final output current.

The second current source shown in FIG. 2B is similar in form and function to the first current source already described with reference to FIG. 2A and therefore, any further explanation will be omitted.

The result of the operation performed by the second current source 107 is contrasted to the first current source 106 as follows. The lower the common mode voltage of the differential input signals 101 and 102 is than a voltage level corresponding to threshold voltages Vtn for the NMOS transistors 110 and 112 of the NMOS differential amplifying circuit 100a, the greater amount of the current I2 flows. Additionally, the higher the common mode voltage of the differential input signals 101 and 102 is than the voltage level corresponding to the threshold voltages Vtn, the smaller amount of the current I2 flows. Namely, when the common mode voltage of the differential input signals 101 and 102 is lower than the voltage level corresponding to Vtn, the NMOS differential amplifying circuit 100a stops operating so that the amount of the current I2 flowing through the PMOS differential amplifying circuit 100b is increased to compensate for the final output current.

As described above, the conventional LVDS input buffer is constructed to maintain the amount of the output current at a constant level so that the voltage level input to the comparison circuit 100c maintains the same. However, the conventional LVDS receiver has difficulties in providing properly designed first and second current sources for supplying respective currents to the differential amplifying circuits 100a and 100b. In addition, it is difficult to maintain the amount of current during high speed operation when the input voltage level is near the center of the common mode input voltage range or at ends of the rail-to-rail common mode input voltage range, which may cause variation in the input voltage level applied to the comparison circuit 100c.

### SUMMARY OF THE INVENTION

The present invention is directed to a low voltage differential signaling (LVDS) input buffer that obviates one or more of the problems associated with the limitations and disadvantages of the conventional approach.

In one aspect, the present invention is directed to an LVDS input buffer including an NMOS differential amplifying circuit, a PMOS differential amplifying circuit, a first level-shift circuit, a second level-shift circuit and an output coupling circuit. The first level-shift circuit level-shifts a differential input signal to a first input voltage range permitted by the NMOS differential amplifying circuit to provide the level-shifted differential input signal to the NMOS differential amplifying circuit. The second level-shift circuit level-shifts the differential input signal to a second input voltage range permitted by the PMOS differential amplifying circuit to provide the level-shifted differential input signal to the PMOS differential amplifying circuit. The output coupling circuit couples a first differential output signal of the NMOS differential amplifying circuit to a second differential output signal of the PMOS differential amplifying circuit to generate a third differential output signal.

In one embodiment, the NMOS differential amplifying circuit includes: a current source configured to supply a current from a first voltage; first and second input NMOS transistors whose first current electrodes are coupled to the current source configured to receive the differential input signal; and first and second PMOS load transistors whose first current electrodes are coupled to a second voltage and whose second current electrodes are coupled to second current electrodes of the first and second input NMOS transistors, respectively.

In another embodiment, the first input voltage range permitted by the NMOS differential amplifying circuit is from about one-half of a difference between the first and second voltages to about the second voltage. In another embodiment, the first voltage corresponds to a ground voltage and the second voltage corresponds to a power supply voltage.

In another embodiment, the PMOS differential amplifying circuit includes: a current source coupled to a second voltage to supply a current; first and second input PMOS transistors whose first current electrodes are coupled to the current source configured to receive the differential input signal; and first and second NMOS load transistors whose first current electrodes are coupled to a first voltage and whose second current electrodes are coupled to second current electrodes of the first and second input PMOS transistors, respectively.

In another embodiment, the second input voltage range permitted by the PMOS differential amplifying circuit is from about the first voltage to about one-half of a difference between the first and second voltages. In another embodiment, the first voltage corresponds to a ground voltage and the second voltage corresponds to a power supply voltage.

In another embodiment, the first level-shift circuit includes: a current source coupled to the second voltage to supply a current; and a variable load element coupled to the current source in serial, wherein a load of the variable load element is varied according to a voltage level of the differential input signal to generate input signals for the NMOS differential amplifying circuit at a node where the current source and the variable load element are coupled to each other.

In another embodiment, the second level-shift circuit includes: a current source coupled to the first voltage to supply a current; and a variable load element coupled to the current source in serial, wherein a load of the variable load element is varied according to a voltage level of the differential input signal to generate input signals for the PMOS differential amplifying circuit at a node where the current source and the variable load element are coupled to each other.

In another embodiment, the LVDS input buffer further comprises a comparison circuit configured to compare two input signals of the third differential output signal to generate a logic signal.

In another embodiment, the output coupling circuit includes: a third PMOS transistor supplied with a mirror current of the first PMOS load transistor of the NMOS differential amplifying circuit; and a fourth PMOS transistor supplied with a mirror current of the second PMOS load transistor of the NMOS differential amplifying circuit, wherein the output coupling circuit combines the mirror currents of the third and fourth PMOS transistors with the second differential output signal of the PMOS differential amplifying circuit, respectively, to generate the third differential input signal.

In another embodiment, the output coupling circuit includes: a third NMOS transistor supplied with a mirror current of the first NMOS load transistor of the PMOS differential amplifying circuit; and a fourth NMOS transistor supplied with a mirror current of the second NMOS load transistor of the PMOS differential amplifying circuit, wherein the output coupling circuit combines the mirror currents of the third and fourth NMOS transistors with the first differential output signal of the NMOS differential amplifying circuit, respectively, to generate the third differential input signal.

In another aspect, the present invention is directed to a method of operating an LVDS input buffer having a rail-to-rail structure. In the method, a differential input signal is level-shifted to a first input voltage range permitted by an NMOS differential amplifying circuit to provide the level-shifted differential input to the NMOS differential amplifying circuit. The differential input signal is level-shifted to a second input voltage range permitted by a PMOS differential amplifying circuit to provide the level-shifted differential input to the PMOS differential amplifying circuit. A final output signal is generated based on output signals of the NMOS differential amplifying circuit and the PMOS differential amplifying circuit.

In one embodiment, the first input voltage range permitted by the NMOS differential amplifying circuit is from about one-half of a difference between a first and second voltages to about the second voltage, wherein the NMOS differential amplifying circuit is coupled between the first and second voltages.

In another embodiment, the second input voltage range permitted by the PMOS differential amplifying circuit is from about a first voltage to about one-half of a difference between the first voltage and a second voltage, wherein the PMOS differential amplifying circuit is coupled between the first and second voltages.

In another embodiment, the first voltage corresponds to a ground voltage and the second voltage corresponds to a power supply voltage.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is an exemplary circuit diagram illustrating a conventional low voltage differential signaling (LVDS) input buffer.

FIGS. 2A and 2B are exemplary circuit diagrams illustrating a current source of a differential amplifying circuit of the conventional LVDS input buffer in FIG. 1.

FIG. 3A is a circuit diagram illustrating a low voltage differential signaling input buffer according to an example embodiment of the present invention.

FIG. 3B is a circuit diagram illustrating a low voltage differential signaling input buffer according to another example embodiment of the present invention.

FIG. 4A is a schematic view illustrating a voltage level of a signal input to respective differential amplifying circuits of the conventional low voltage differential signaling input buffer.

FIG. 4B is a schematic view illustrating a voltage level of a signal input to respective differential amplifying circuits of a low voltage differential signaling input buffer according to an example embodiment of the present invention.

### DETAILED DESCRIPTION OF THE INVENTION

The present invention will now be explained in detail with reference to the accompanying drawings.

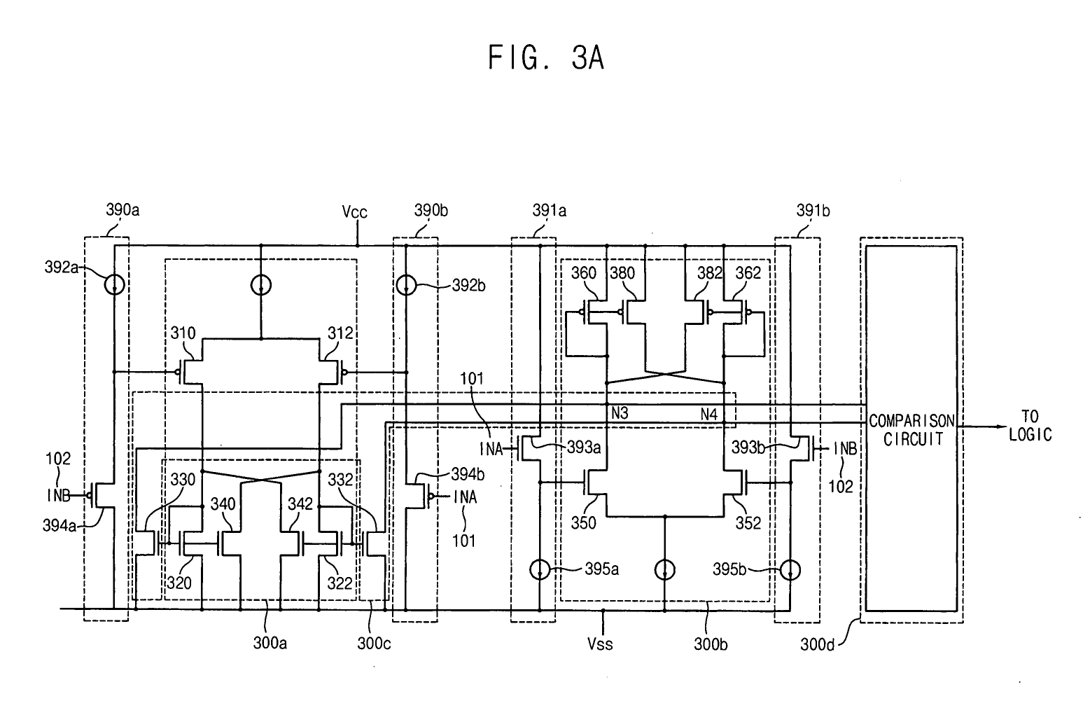

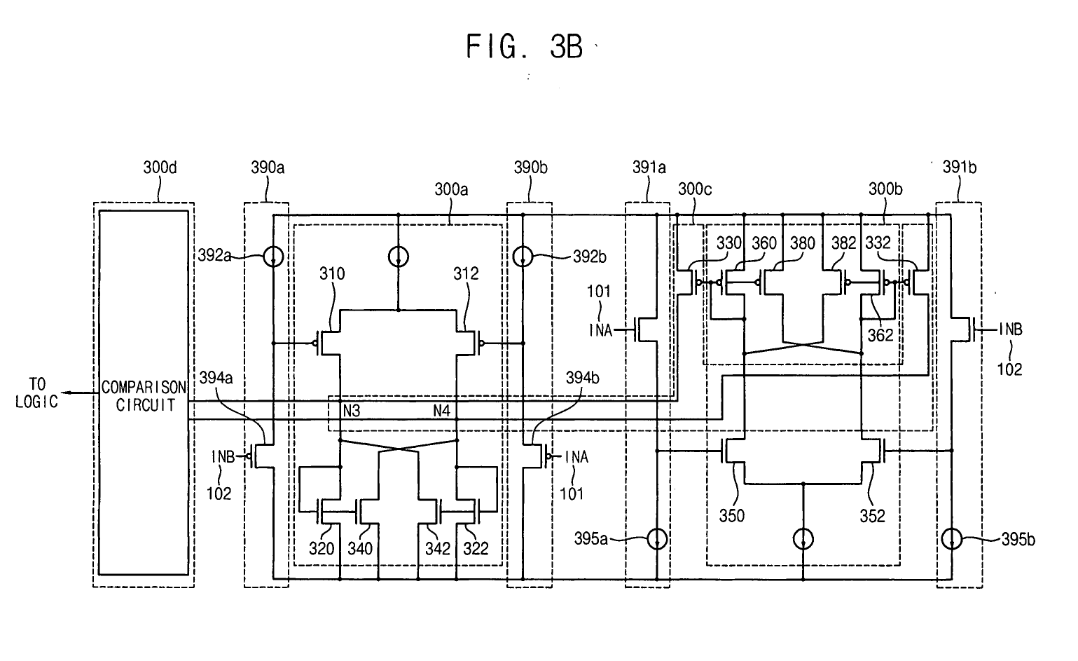

FIG. 3A is a circuit diagram illustrating a low voltage differential signaling (LVDS) input buffer according to an example embodiment of the present invention and FIG. 3B is a circuit diagram illustrating a low voltage differential signaling input buffer according to another example embodiment of the present invention.

Referring to FIG. 3A, the LVDS input buffer according to an example embodiment of the present invention includes a PMOS differential amplifying circuit 300a, an NMOS differential amplifying circuit 300b, an output circuit 300c and a comparison circuit 300d.

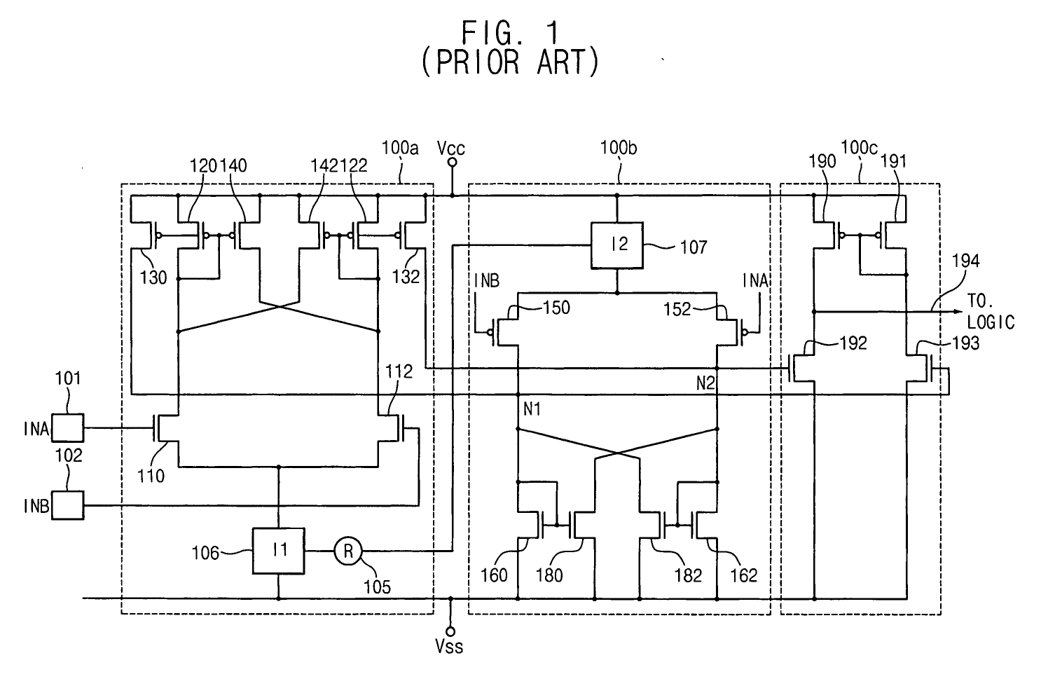

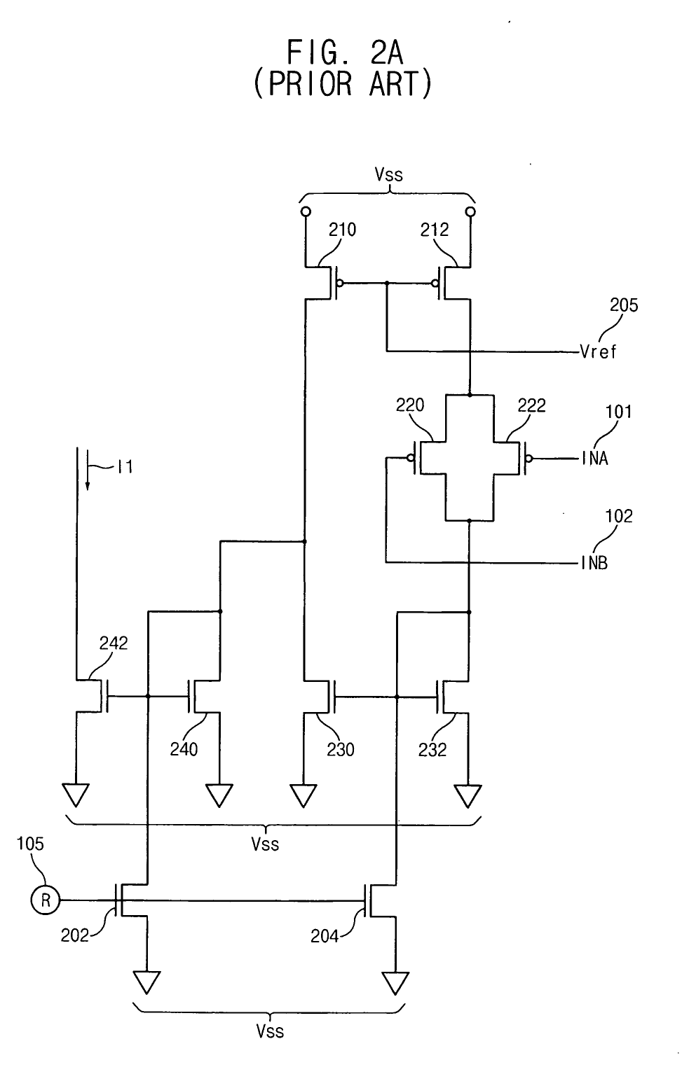

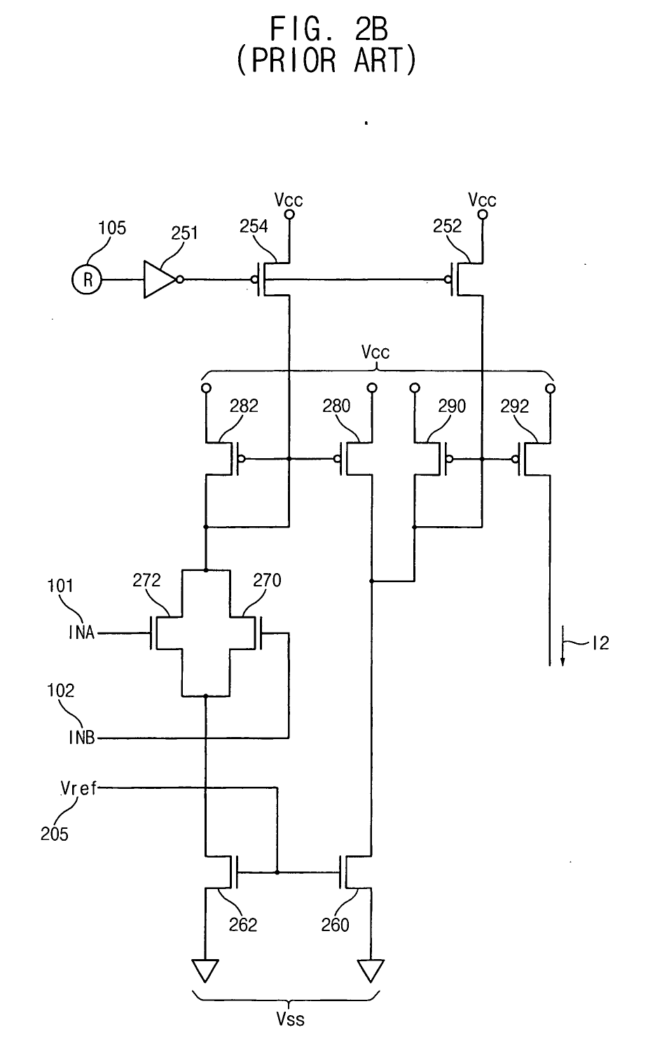

As compared with the differential amplifying circuits 100a and 100b of the conventional embodiments described above in connection with FIG. 1, the first level shift circuits 390a and 390b and second level shift circuits 391a and 391b are added to the LVDS input buffer according to the example embodiment of FIG. 3A to provide a level shifted differential input signal to the respective differential amplifying circuits 300a and 300b.

The first level shift circuits 390a and 390b each shift the voltage level of input signals INA (101) and INB (102) of the differential input signal to apply the level-shifted signals to control electrodes of input PMOS transistors 310 and 312, respectively. The first level shift circuits 390a and 390b include current sources 392a and 392b that are serially coupled to a power supply voltage Vcc and variable load elements 394a and 394b that are serially coupled to the current sources 392a and 392b, respectively.

In one example, the current sources 392a and 392b can be implemented in MOS transistors and the variable load elements 394a and 394b can be implemented in PMOS transistors. The differential input signal 101 and 102 is applied to the control electrodes of the variable load elements 394a and 394b (e.g., PMOS transistors), respectively, and the impedance values of the variable load elements 394a and 394b are varied according to voltage levels of the differential input signal 101 and 102.

The signals input to the input PMOS transistors 310 and 312 of the PMOS differential amplifying circuit are generated at respective nodes coupled between the current sources 392a, 392b and the PMOS transistors 394a and 394b. Thus, the differential input signal passing through the first level shift circuits 390a and 390b is level-shifted with respect to the common input voltage range of the differential input signal INA and INB to a voltage range required for proper operation of the PMOS differential amplifying circuit.

Therefore, when the entire common input mode voltage has a voltage range from about Vss to about Vcc, the input signal of the PMOS differential amplifying circuit has a voltage range of about Vss to about (Vcc−Vss)/2. For example, when the entire common input mode voltage has a voltage range from about 0 to about 2.4 volts, the first level shift circuits 390a and 390b provide the differential input signal ranging from about 0 to about (2.4−0)/2 (i.e., 1.2 volts).

To limit the voltage level of the differential input signal to an acceptable level, the respective sizes of the transistors of the current sources 392a and 392b and the variable load elements 394a and 394b may be adjusted. In other words, when the differential input signal has a voltage level that is close to Vcc, the impedance of the PMOS transistors 394a and 394b is adjusted such that the voltage level about (Vcc−Vss)/2 may be input to the input PMOS transistors 310 and 312. Conversely, when the differential input signal has a voltage level that is close to Vss, the impedance of the PMOS transistors 394a and 394b is reduced so that the voltage level input to the input PMOS transistors 310 and 312 is about (Vcc−Vss)/2. The level-shifted voltage may range from about Vss to about (Vcc−Vss)/2 in one embodiment, however, the voltage limit of the range may be varied according to a particular application.

Second level shift circuits 391a and 391b can be similar in form and function to the first level shift circuits 390a and 390b.

The second level shift circuits 391a and 391b perform level shifting on the input signals INA (101) and INB (102) of the differential input signal to provide level-shifted input signals to control electrodes of input PMOS transistors 350 and 352, respectively. The second level shift circuits 391a and 391b include variable load elements 393a and 393b that are serially coupled to the power supply voltage Vcc and the current sources 395a and 395b that are serially coupled to the variable load elements 393a and 393b, respectively.

The current sources 395a and 395b can be implemented in MOS transistors and the variable load elements 393a and 393b can be implemented in NMOS transistors. The differential input signal 101 and 102 is applied to the control electrodes of the variable load elements 393a and 393b (e.g., NMOS transistors), respectively, and impedance values of the variable load elements 393a and 393b are varied according to voltage levels of the differential input signal 101 and 102.

The signals input to the input transistors 350 and 352 of the NMOS differential amplifying circuit are generated at respective nodes coupled between the currents 395a, 395b and the NMOS transistors 393a and 393b. Thus, the differential input signal passing through the second level shift circuits 391a and 391b is level-shifted with respect to the common input voltage range of the differential input signal INA and INB to a voltage range required for proper operation of the NMOS differential amplifying circuit.

Therefore, when the entire common input mode voltage has a voltage range from about Vss to about Vcc, the input signal of the PMOS differential amplifying circuit has a voltage range of about (Vcc−Vss)/2 to about Vcc. For example, when the entire common input mode voltage has a voltage range from about 0 to about 2.4 volts, the second level shift circuits 391a and 391b provide the differential input signal ranging from about (2.4−0)/2 (i.e., 1.2 volts) to about 2.4 volts.

To limit the voltage level of the differential input signal to an acceptable level, the respective sizes of transistors of the current sources 395a and 395b and the variable load elements 393a and 393b may be adjusted. In other words, when the differential input signal has a voltage level close to Vcc, the impedance of the NMOS transistors 395a and 395b is reduced so that the voltage level about Vcc may be input to the input NMOS transistors 350 and 352. Conversely, when the differential input signal has a voltage level close to Vss, the impedance of the NMOS transistors 393a and 393b is adjusted such that the voltage level input to the input NMOS transistors 350 and 352 is about (Vcc−Vss)/2. The level-shifted voltage may range from (Vcc−Vss)/2 to Vcc in one embodiment, however, the voltage limit of the range may be varied according to a particular application, as illustrated above for the PMOS differential amplifying circuit.

The output circuit 300c combines outputs of the PMOS differential amplifying circuit 300a with outputs of the NMOS differential amplifying circuit 300b to provide a differential output signal based on the combined outputs of the respective amplifying circuits. Particularly, the output circuit 300c includes NMOS transistors 330 and 332 supplied with mirrored currents of NMOS transistors 320 and 322 of the PMOS differential amplifying circuit 300a. The output coupling circuit 300c combines the mirrored currents of the NMOS transistors 330 and 332 with output signals of the NMOS differential amplifying circuit 300b to provide the combined output signal to the comparison circuit 300d. The mirrored currents of the NMOS transistors 330 and 332 are coupled to currents flowing through the NMOS input transistors 350 and 352 of the NMOS differential amplifying circuit 300b at first and second nodes N3 and N4, respectively.

The LVDS input buffer in FIG. 3B has the same structure as in FIG. 3A except for the output circuit 300c.

The output circuit 300c of FIG. 3B includes PMOS transistors 330 and 332 that are supplied with mirrored currents of PMOS transistors 360 and 362 of the NMOS differential amplifying circuit 300b. The output coupling circuit 300c combines the output signals of the NMOS differential amplifying circuit 300b (i.e., the mirrored currents of the PMOS transistors 330 and 332) with the output signals of the PMOS differential amplifying circuit 300a (i.e., the current flowing through the NMOS transistors 320 and 322 of the PMOS differential amplifying circuit 300a). The mirrored currents of the PMOS transistors 330 and 332 are coupled to currents flowing through the PMOS input transistors 310 and 312 of the PMOS differential amplifying circuit 300a at the first and second nodes N3 and N4, respectively.

The comparison circuit 300c provides a logic signal to a logic element of the host device using the received combined outputs of the NMOS and PMOS differential amplifying circuits 100a and 100b.

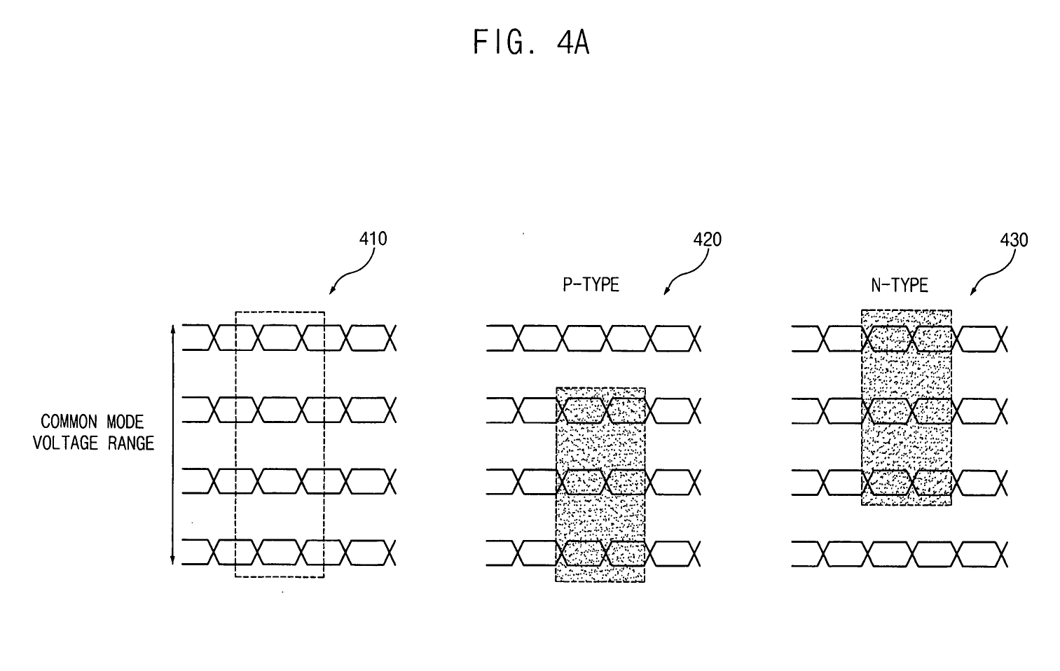

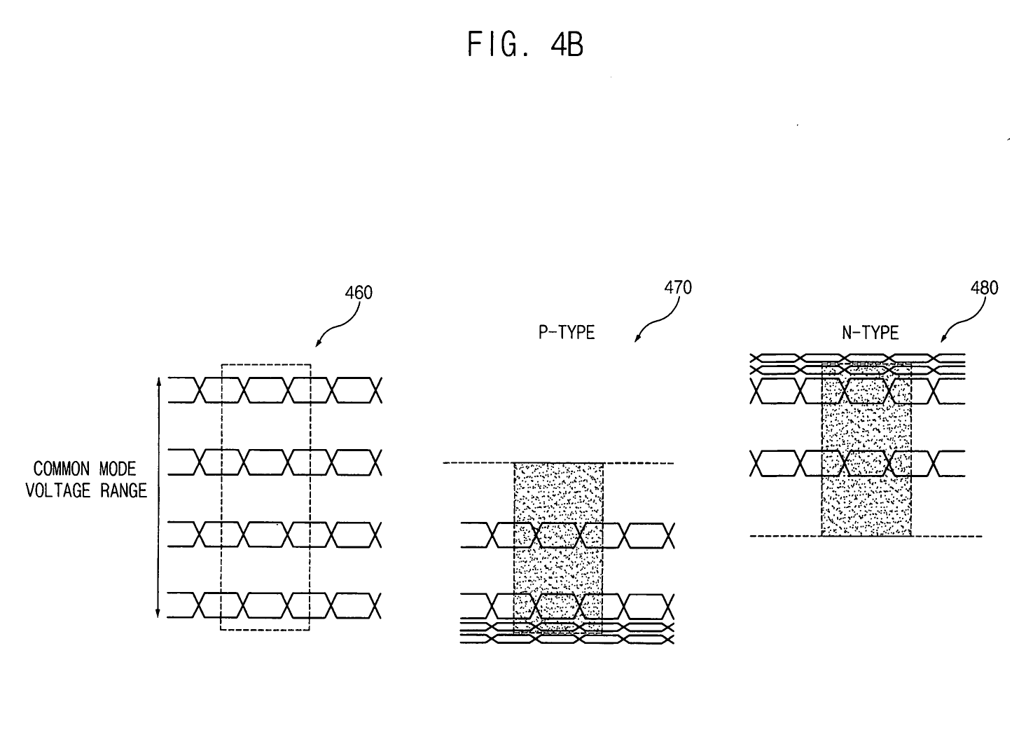

FIG. 4A illustrates the common mode voltage level of the differential input signal in the conventional LVDS input buffer and input voltage ranges of the respective differential amplifying circuits and FIG. 4B illustrates the voltage level of the differential input signal that is shifted to an allowable input voltage range of the respective amplifying circuits by the level shifter added to the LVDS input buffer according to an example embodiment of the present invention.

Reference numeral “410” in FIG. 4A represents the common mode voltage level of the differential input signal 101 and 102 input to the conventional LVDS input buffer. An upper limit of the common mode voltage level may correspond to a maximum allowed voltage (for example, 2.4 volts) and a lower limit may correspond to a minimum allowed voltage (for example, 0 volt).

A reference numeral “420” represents the input voltage level of the PMOS amplifying circuit and a shaded area represents a voltage range permitted by the PMOS amplifying circuit. Therefore, an upper limit of the shaded area may correspond to a voltage level about Vcc−|Vtp| and a lower limit may correspond to the minimum allowed voltage (for example, 0V) of the PMOS amplifying circuit. Similarly, a reference numeral “430” in FIG. 4A represents the input voltage level of the NMOS amplifying circuit and a shaded area represents a voltage range permitted by the NMOS amplifying circuit. Therefore, an upper limit of the shaded area may correspond to the maximum allowed voltage and a lower limit may correspond to the voltage level corresponding to about Vtn.

As seen from the voltage range in “420” and “430”, the differential input signal INA and INB input to the differential amplifying circuits of the conventional LVDS input buffer maintains the entire common mode voltage range. Therefore, each of the differential amplifying circuits can operate only in a permissible voltage range of the differential amplifying circuit. Namely, the PMOS amplifying circuit may not operate at a voltage level above Vcc−|Vtp| and the NMOS amplifying circuit may not operate at a voltage level below Vtn.

Reference numerals “460”, “470” and “480” shown in FIG. 4B identify substantially the same as those represented by the reference numerals “410”, “420” and “430” in FIG. 4A.

As compared with the conventional LVDS input buffer in FIG. 4A, the differential input signal 101, 102 is level-shifted and input to the respective differential amplifying circuits. It can be seen from “470” that the differential input signal is level-shifted below a voltage level of about Vcc−|Vtp| that is the upper limit of the permissible voltage range of the PMOS amplifying circuit. In “480”, the differential input signal is level shifted above a voltage level about Vtn that is the lower limit of the permissible voltage range of the NMOS amplifying circuit.

Using the method of level shifting the LVDS input signals according to example embodiments of the present invention, the PMOS and NMOS differential amplifying circuits may be operable at any input voltage level of the differential input signal. Additionally, the amount of the current provided to the respective differential amplifying circuits may be maintained at a substantially constant level. Therefore, the voltage level of the final output signal may be maintained at a constant level without the need for adjusting the amount of the current provided to the differential amplifying circuits.

Adjusting the amount of current may cause additional noise to be generated in the power supply voltage during high-speed operation. This is mitigated in the example embodiment of the present invention. In addition, the design of a current source that simply supplies a constant amount of current is relatively simple compared with the variable current source having high design complexities.

Namely, a level shift circuit receiving the differential input signal may be used in the LVDS input buffer having a rail-to-rail structure to provide a constant amount of the current to the respective differential amplifying circuits, while maintaining a constant output voltage level to operate at high speed. Additionally, compared with the conventional approach of using the current source supplying a variable amount of current, the use of the level shift circuit achieves the same effect and moreover, the supply of the constant current can reduce the noise present on the power supply voltage.

While this invention has been particularly shown and described with references to preferred embodiments thereof, it will be understood by those skilled in the art that various changes in form and details may be made herein without departing from the spirit and scope of the invention as defined by the appended claims.

1. A low voltage differential signaling (LVDS) input buffer, comprising:
an NMOS differential amplifying circuit;
a PMOS differential amplifying circuit;
a first level shift circuit configured to level-shift a differential input signal to a first input voltage range permitted by the NMOS differential amplifying circuit and to provide the level-shifted differential input signal to the NMOS differential amplifying circuit;
a second level-shift circuit configured to level-shift the differential input signal to a second input voltage range permitted by the PMOS differential amplifying circuit and to provide the level-shifted differential input signal to the PMOS differential amplifying circuit; and
an output coupling circuit configured to couple a first differential output signal of the NMOS differential amplifying circuit to a second differential output signal of the PMOS differential amplifying circuit to generate a third differential output signal.

2. The LVDS input buffer of claim 1, wherein the NMOS differential amplifying circuit includes:
a current source configured to supply a current from a first voltage;
first and second input NMOS transistors whose first current electrodes are coupled to the current source configured to receive the differential input signal; and
first and second PMOS load transistors whose first current electrodes are coupled to a second voltage and whose second current electrodes are coupled to second current electrodes of the first and second input NMOS transistors, respectively.

3. The LVDS input buffer of claim 2, wherein the first input voltage range permitted by the NMOS differential amplifying circuit is from about one-half of a difference between the first and second voltages to about the second voltage.

4. The LVDS input buffer of claim 3, wherein the first voltage corresponds to a ground voltage and the second voltage corresponds to a power supply voltage.

5. The LVDS input buffer of claim 1, wherein the PMOS differential amplifying circuit includes:
a current source coupled to a second voltage to supply a current;
first and second input PMOS transistors whose first current electrodes are coupled to the current source configured to receive the differential input signal; and
first and second NMOS load transistors whose first current electrodes are coupled to a first voltage and whose second current electrodes are coupled to second current electrodes of the first and second input PMOS transistors, respectively.

6. The LVDS input buffer of claim 5, wherein the second input voltage range permitted by the PMOS differential amplifying circuit is from about the first voltage to about one-half of a difference between the first and second voltages.

7. The LVDS input buffer of claim 6, wherein the first voltage corresponds to a ground voltage and the second voltage corresponds to a power supply voltage.

8. The LVDS input buffer of claim 2, wherein the first level-shift circuit includes:
a current source coupled to the second voltage to supply a current; and
a variable load element coupled to the current source in serial, wherein a load of the variable load element is varied according to a voltage level of the differential input signal to generate input signals for the NMOS differential amplifying circuit at a node where the current source and the variable load element are coupled to each other.

9. The LVDS input buffer of claim 5, wherein the second level-shift circuit includes:
a current source coupled to the first voltage to supply a current; and
a variable load element coupled to the current source in serial, wherein a load of the variable load element is varied according to a voltage level of the differential input signal to generate input signals for the PMOS differential amplifying circuit at a node where the current source and the variable load element are coupled to each other.

10. The LVDS input buffer of claim 1, further comprising a comparison circuit configured to compare two input signals of the third differential output signal to generate a logic signal.

11. The LVDS input buffer of claim 2, wherein the output coupling circuit includes:
a third PMOS transistor supplied with a mirror current of the first PMOS load transistor of the NMOS differential amplifying circuit; and
a fourth PMOS transistor supplied with a mirror current of the second PMOS load transistor of the NMOS differential amplifying circuit, wherein the output coupling circuit combines the mirror currents of the third and fourth PMOS transistors with the second differential output signal of the PMOS differential amplifying circuit, respectively, to generate the third differential input signal.

12. The LVDS input buffer of claim 5, wherein the output coupling circuit includes:
a third NMOS transistor supplied with a mirror current of the first NMOS load transistor of the PMOS differential amplifying circuit; and
a fourth NMOS transistor supplied with a mirror current of the second NMOS load transistor of the PMOS differential amplifying circuit, wherein the output coupling circuit combines the mirror currents of the third and fourth NMOS transistors with the first differential output signal of the NMOS differential amplifying circuit, respectively, to generate the third differential input signal.

13. A method of operating a low voltage differential signaling (LVDS) input buffer, wherein the low voltage differential signaling (LVDS) input buffer has a rail-to-rail structure, comprising:
level-shifting a differential input signal to a first input voltage range permitted by an NMOS differential amplifying circuit and providing the level-shifted differential input to the NMOS differential amplifying circuit;
level-shifting the differential input signal to a second input voltage range permitted by a PMOS differential amplifying circuit and providing the level-shifted differential input to the PMOS differential amplifying circuit; and
generating a final output signal based on output signals of the NMOS differential amplifying circuit and the PMOS differential amplifying circuit.

14. The method of claim 13, wherein the first input voltage range permitted by the NMOS differential amplifying circuit is from about one-half of a difference between a first and second voltages to about the second voltage, wherein the NMOS differential amplifying circuit is coupled between the first and second voltages.

15. The method of claim 14, wherein the first voltage corresponds to a ground voltage and the second voltage corresponds to a power supply voltage.

16. The method of claim 13, wherein the second input voltage range permitted by the PMOS differential amplifying circuit is from about a first voltage to about one-half of a difference between the first voltage and a second voltage, wherein the PMOS differential amplifying circuit is coupled between the first and second voltages.

17. The method of claim 16, wherein the first voltage corresponds to a ground voltage and the second voltage corresponds to a power supply voltage.
